(19) United States
(12) Patent Application Publication
(10) Pub. No.: US 2014/0036439 A1
(43) Pub. Date: Feb. 6, 2014

(54) ELECTRONIC DEVICE

(71) Applicant: WEN-HUNG HUANG, Tu-Cheng (TW)

(72) Inventor: WEN-HUNG HUANG, Tu-Cheng (TW)

(73) Assignee: HON HAI PRECISION INDUSTRY CO., LTD., Tu-Cheng (TW)

(21) Appl. No.: 13/587,953

(22) Filed: Aug. 17, 2012

(30) Foreign Application Priority Data
Aug. 3, 2012 (TW) 101128053

(51) Int. Cl. H05K 7/20

(52) U.S. Cl. 361/692

(57) ABSTRACT

An electronic device includes two opposite sidewalls, a first end wall, and a second end wall. A first partition plate and a second partition plate are connected between the sidewalls. First fans are installed to a middle of the second partition plate, and Second fans are installed to two opposite ends of the second partition plate. An air duct is installed between the second partition plate and the second end wall, aligning with the first fans. Each second fan blows in a direction opposite to that each first fan does. The first fans generate airflow entering between the first partition plate and the second partition plate from the first end wall, and the first partition plate to exhaust through the second end wall. The second fans generate airflow entering between the first partition plate and the second partition plate from the second end wall.

### BACKGROUND

1. Technical Field

The disclosure relates to electronic devices and, perpendicularly, to an electronic device with a heat dissipation system.

2. Description of Related Art

Electronic components, such as expansion cards, generate heat during operation, which can deteriorate their operational stability. Thus, the heat must be removed quickly to ensure normal operation of the expansion cards. A heat dissipation system is usually installed in an electronic device, such as a server, for dissipating the heat.

Referring to FIG. 2, an electronic device 100 includes a rectangular casing 12, a first partition plate 13 installed in the casing 12, a second partition plate 14 spaced from the first partition plate 13 and installed in the casing 12, and a plurality of fans 15 installed to the second partition plate 14. A plurality of expansion cards 18 is respectively received in two corners of the casing 12 away from the second partition plate 14. A middle of the first partition plate 13 defines a plurality of vents 132, and the second partition plate 14 defines a plurality of through holes 142 respectively aligning with the fans 15. The fans 15 operate and draw air from the vents 132 to generate airflow. The airflow enters a space between the first partition plate 13 and the second partition plate 14. The airflow flows between and around the expansion cards 18 to remove heat. However, the fans 15, aligning with the expansion cards 18 and located at two opposite ends of the second partition plate 14, are away from the vents 132, such that only small amount of airflow reaches the expansion cards 18, which may cause the expansion cards 18 to be over-heated. In that situation, the temperatures of the expansion cards 18 of the electronic device 100 are high.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a cross-sectional view of an embodiment of an electronic device.

FIG. 2 is a cross-sectional view of an electronic device of a related art.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

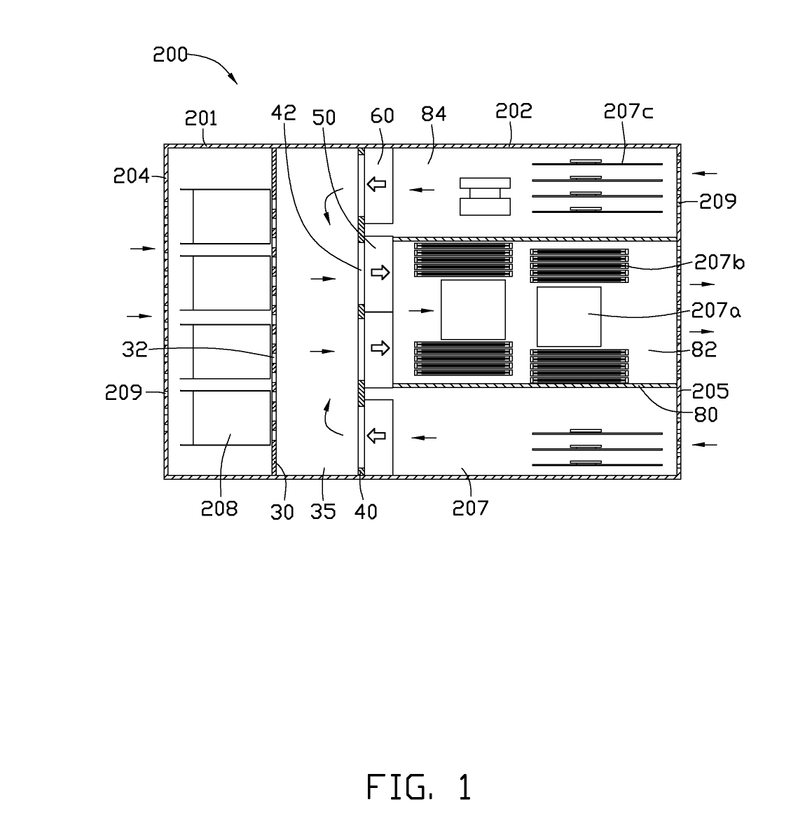

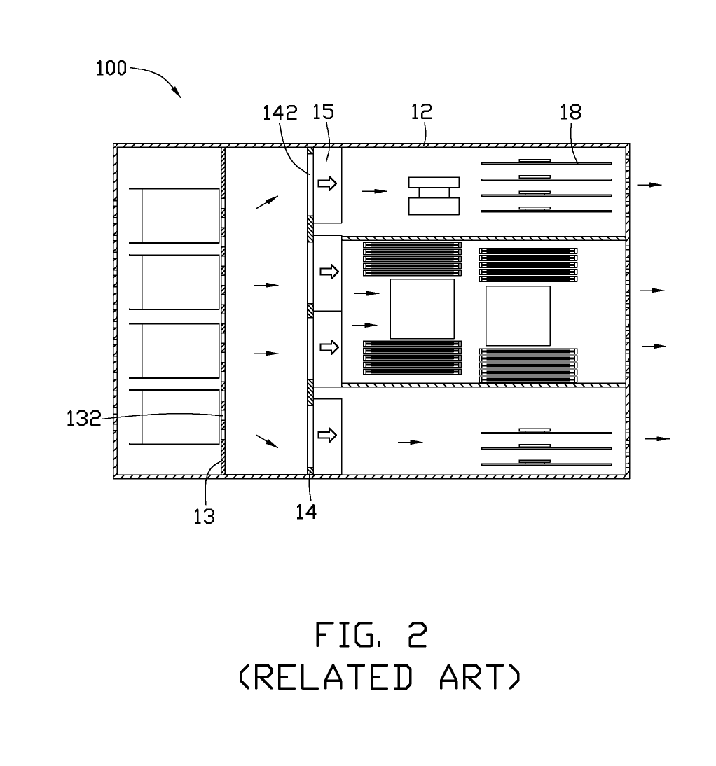

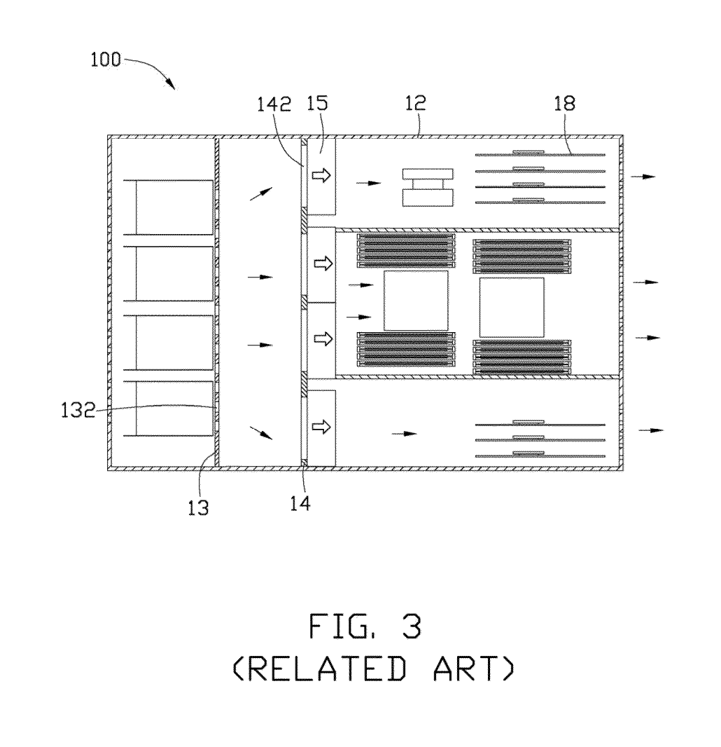

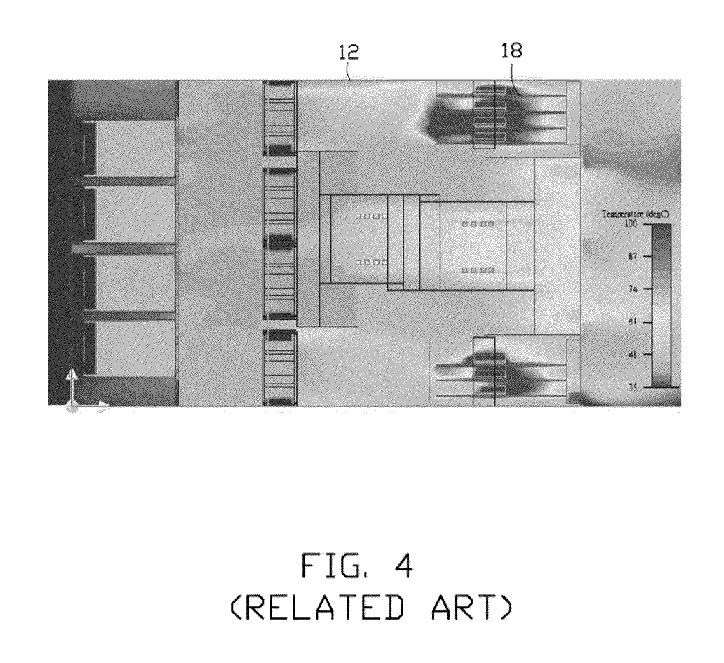

FIG. 1 shows an embodiment of an electronic device 200. The electronic device 200 includes a chassis 201. The chassis 201 includes two opposite sidewall 202, a first end wall 204 perpendicularly connected between first ends of the sidewalls 202. A second end wall 205 perpendicularly connected between second ends of the sidewalls 202 opposite to the first end wall 204. A circuit board 207 adjacent to the second end wall 205 and a plurality of hard disk drives 208 adjacent to the first end wall 204. A central processing unit (CPU) 207a and a plurality of memory chips 207b are mounted on a middle of the circuit board 207, and a plurality of expansion cards 207c is mounted on two opposite sides of the circuit board 207. The first end wall 204 and the second end wall 205 each define a plurality of vents 209. In the embodiment, the electronic device 200 is a server.

The electronic device 200 further includes a first partition plate 30 perpendicularly connected between the sidewalls 202 adjacent to the first end wall 204, and a second partition plate 40 perpendicularly connected between the sidewalls 202 and spaced from the first partition plate 30. The second partition plate 40 is located at a side of the first partition plate 30 opposite to the first end wall 204. A plurality first fans 50 is installed to a middle of a side of the second partition plate 40 opposite to the first partition plate 30. A plurality of second fans 60 is respectively installed to two opposite ends of the side of the second partition plate 40. An air duct 80 is mounted on the circuit board 207, aligning with the first fans 50. The first partition plate 30 and the second partition plate 40 cooperatively bound a space 35. The first partition plate 30 defines a plurality of through holes 32 aligned with the first fans 50. The second partition plate 40 defines a plurality of vents 42 each aligning with a corresponding one of the first fans 50 and the second fans 60. The hard disk drives 208 are installed between the first end wall 204 and the first partition plate 30. Each second fan 60 blows in a direction opposite to that each first fan 50 does. The air duct 80 defines a first air channel 82 for receiving the CPU 207a and the memory chips 207b. The air duct 80 and the sidewalls 202 cooperatively bound two second air channels 84 for receiving the expansion cards 207c.

In use, a first part of airflow generated by the first fans 50 enters the chassis 201 through the vents 209. The airflow then extends through the hard disk drives 208, the through holes 32, the corresponding vents 42, the first air channel 82, the CPU 207a and the memory chips 207b, and exhausts through the middle portion of the vents 209. Two second parts of airflow respectively generated by the second fans 60 enter the chassis 201 through both end portions of the vents 209, flow through the expansion cards 207c, and enter the space 35. The direction of the first part of airflow of the first fans 50 is reverse to the direction of the second airflow of the second fans 60. The second parts of airflow of the second fans 60 in the space 35 flow through the first air channel 82 by the first fans 50, to increase the volume of air flowing through the CPU 207a and the memory chips 207b, thereby increasing the effectiveness of dissipating heat from the CPU 207a and the memory chips 207b.

The temperatures of the CPU 207a, the memory chips 207b, and the expansion cards 207c of the electronic device 200 are low.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An electronic device, comprising:
a chassis comprising two opposite sidewalls, a first end wall connected between first ends of the sidewalls and defining a plurality of first vents, and a second end wall connected between second ends of the sidewalls and defining a plurality of second vents;
a first partition plate connected between the sidewalls adjacent to the first end wall, the first partition plate defining a plurality of third vents;
a second partition plate connected between the sidewalls and adjacent to the first end wall, the second partition plate spaced from the first partition plate and located at a side of the first partition plate opposite to the first end wall, the second partition plate defining a plurality of fourth vents;
a plurality of first fans installed to a middle of the second partition plate and aligning with corresponding ones of the fourth vents;
a plurality of second fans respectively installed to two opposite ends of the second partition plate and aligning with corresponding ones of the fourth vents; and
an air duct installed in the chassis between the second partition plate and the second end wall and aligning with the first fans; wherein each second fan blows in a direction opposite to that each first fan does, the first fans generate a first part of airflow entering a space between the first partition plate and the second partition plate from the first vents of the first end wall and the third vents of the first partition plate, the first part of airflow extends through the air duct to exhaust through the second vents of middle portion of the second end wall aligning with the air duct, the second fans generate two second parts of airflow entering the space between the first partition plate and the second partition plate from the second vents of both end portions of the second end wall at opposite sides of the air duct.

2. The electronic device of claim 1, wherein an airflow direction generated by the first fans is reverse to an airflow direction generated by the second fans.

3. The electronic device of claim 1, wherein the air duct defines a first air channel for receiving a central processing unit and a plurality of memory chips.

4. The electronic device of claim 3, wherein the air duct and the sidewalls cooperatively bound two second air channels aligning with the second fans, for receiving a plurality of expansion cards.

5. The electronic device of claim 1, wherein the third vents of the first partition plate align with the first fans.

6. An electronic device, comprising:
a chassis comprising two opposite sidewalls, a first end wall connected between first ends of the sidewalls and defining a plurality of first vents, and a second end wall connected between second ends of the sidewalls and defining a plurality of second vents;
a first partition plate connected between the sidewalls adjacent to the first end wall, the first partition plate defining a plurality of third vents in a middle of the first partition plate;
a second partition plate connected between the sidewalls and adjacent to the first end wall, the second partition plate spaced from the first partition plate and located at a side of the first partition plate opposite to the first end wall, the second partition plate defining a plurality of fourth vents;
a plurality of first fans installed to a middle of the second partition plate;
a plurality of second fans respectively installed to two opposite ends of the second partition plate;
a circuit board received in the chassis among the sidewalls, the second end wall, and the second partition plate, wherein a central processing unit (CPU) and a plurality of memory chips are installed on a middle of the circuit board and align with the first fans, a plurality of expansion cards is installed on two opposite sides of the circuit board and aligns with the corresponding second fans;
an air duct installed on the circuit board, aligning with the first fans, and enclosing the CPU and the memory chips; and
a plurality of hard disk drives received in the chassis between the first end wall and the first partition plate; wherein each second fan blows in a direction opposite to that each first fan does, the first fans generate a first part of airflow entering a space between the first partition plate and the second partition plate from the first vents of the first end wall, the hard disk drives, and the third vents of the first partition plate, the first part of airflow extends through the fourth vents, the air duct, the CPU, and the memory chips, to exhaust through the second vents of middle portion of the second end wall, the second fans generate two second parts of airflow entering the space between the first partition plate and the second partition plate from the second vents of both end portions of the second end wall, the expansion cards, and the fourth vents.

7. The electronic device of claim 6, wherein an airflow direction generated by the first fans is reverse to an airflow direction generated by the second fans.

8. The electronic device of claim 6, wherein the air duct defines a first air channel, the CPU and the memory chips are received in the first air channel.

9. The electronic device of claim 8, wherein the air duct and the sidewalls cooperatively bound two second air channels, the expansion cards are respectively received in the second air channels.

10. The electronic device of claim 6, wherein the third vents of the first partition plate align with the first fans.
